(19) United States
(12) Patent Application Publication
(10) Pub. No.: US 2026/0342052 A1
(43) Pub. Date: Oct. 29, 2026

(54) MICROGRID INTERCONNECT DEVICE (MID) FOR DOUBLED INTERIORS

(71) Applicant: Schneider Electric USA, Inc., Andover, MA (US)

(72) Inventor: Chad R. Mittelstadt, Cedar Rapids, IA (US)

(73) Assignee: Schneider Electric USA, Inc., Boston, MA (US)

(21) Appl. No.: 19/188,319

(22) Filed: Apr. 24, 2025

(51) Int. Cl. H02B 1/04; H02B 3/00; H05K 7/14

(52) U.S. Cl. CPC H02B 1/04; H02B 3/00; H05K 7/1427

(57) ABSTRACT

A method of retrofitting an electrical panel includes removing a plurality of branch circuit breakers from a first interior in a panel housing. Before installing the second interior, the method can include removing one or more nuts mechanically securing one or more corresponding load side electrical connectors of a main breaker to one or more corresponding busses of the interior. The method includes installing a second interior onto the first interior and connecting a microgrid interconnect device (MID) in electrical series between the main breaker and the second interior. The second interior and MID can be integrated together to be installed as one piece onto the first interior.

### BACKGROUND

### 1. Field

The present disclosure relates to electrical panels, and more particularly to microgrid interconnect devices (MIDs) for connecting and disconnecting residential electrical panels such as common service entrance device (CSED) panels from utility grids.

### 2. Description of Related Art

It is common for CSED panels to need an MID, but there is no provision to add an MID to a CSED panel easily. One solution has been to locate an MID inside the meter collar, but that location is not always compliant with utility regulations. Ideally, there would be enough room in the CSED panel itself to locate an MID physically in between the main breaker and the interior. However, in legacy CSED configurations there is not enough room in the vertical direction to fit an MID physically. While there are some new install options for accommodating MID's in CSED panels, they do not solve the problem of retrofitting legacy CSED panels to include MIDs. Existing retrofit solutions require relocating the circuit breakers, which is not ideal. Moreover, traditional MIDs require the utility to shutoff grid power in order to install an MID in an existing panel or system.

The conventional techniques have been considered satisfactory for their intended purpose. However, there is an ever-present need for improved systems and methods for incorporating MIDs with CSED panels, including methods for retrofitting legacy CSED panels to include MIDs. This disclosure provides a solution for this need.

### SUMMARY

A method of retrofitting an electrical panel includes removing a plurality of branch circuit breakers from a first interior in a panel housing. The method includes installing a second interior onto the first interior and connecting a microgrid interconnect device (MID) in electrical series between the main breaker and the second interior.

Connecting the MID can include connecting a first line side connector of the MID to a first load side connector of the main breaker and connecting a second line side connector of the MID to a second load side connector of the main breaker. With the main breaker in an ON state, the main breaker can electrically connect a first line of the electrical panel housing in series with the first line side connector of the MID and can connect a second line of the electrical panel housing in series with the second line side connector of the MID. With the MID in an ON state, the MID can connect the first line side connector of the MID to a first line bus of the second interior and can connect the second line side connector of the MID to a second line bus of the second interior.

Prior to removing the circuit breakers, the plurality of circuit breakers can be installed on the first interior, electrically connecting first and second line busses of the first interior to individual branch circuits by load wires. The method can include mechanically installing the plurality of circuit breakers onto the second interior and electrically connecting first and second line busses of the second interior to each of the circuit breakers of the plurality of circuit breakers. This can include keeping the plurality of circuit breakers electrically connected to the load wires before, during, and after removing the plurality of circuit breakers from the first interior, installing the second interior and the MID, and connecting the MID in series between the first and second lines of the electrical panel housing and the main breaker.

The method can include switching the main breaker to an OFF state to disconnect power to the first interior and removing a dead front from the panel housing to access the first interior before removing the plurality of circuit breakers from the first interior. Connecting the MID in electrical series between the main breaker and the second interior can be performed with the main breaker electrically connected to first and second lines of the panel housing.

The first interior can include a plurality of breaker connectors extending from a first line bus and form a second line bus. The second interior can include a plurality of sockets. Installing the second interior onto the first interior can include securing the first interior to the second interior by interlocking the plurality of breaker connectors of the first interior into the plurality of sockets of the second interior to hold the first and second interiors together.

Prior to removing the plurality of breakers from the first interior, the method can include removing a dead front from the panel housing to provide access to the first interior. After installing the second interior and connecting the MID in electrical series between the main breaker and the second interior, the method can include installing a new dead front to the panel housing.

An apparatus includes an interior for an electrical panel, wherein the interior includes a first line bus and a second line bus, each with a plurality of breaker connectors extending therefrom. A microgrid interconnect device (MID) is mounted to the interior with a first load side connector of the MID connected electrically and mechanically joined to the first line bus. A second load side connector of the MID is connected electrically and mechanically joined to the second line bus.

An MID housing can be included, wherein a switching device is in an interior space of the MID housing. Each of the first load side connector of the MID, the second load side connector of the MID, the first line side connector of the MID, and the second line side connector of the MID can extend from an exterior space, through the MID housing, and into the interior space of the MID housing to electrically connect to the switching device. The interior can include a back surface at a first elevation in a z-direction defined perpendicular to the back surface. Respective terminals of the first and second line side connectors of the MID can be positioned at a second elevation in the z-direction equal to or offset from the first elevation, configured to be joined by respective posts of a previously-installed interior to load side connectors of a main breaker in an electrical panel. The back surface of the interior can include a plurality of sockets configured to receive a plurality of breaker connectors extending from line busses of the previously-installed interior for securing the interior to the previously-installed interior by interlocking the plurality of breaker connectors of the previously-installed interior into the plurality of sockets.

A printed circuit board assembly (PCBA) can be included within the interior space of the MID housing. The PCBA can include a controller configured to control the switching device to switch the switching device between the MID ON state and the MID OFF state. A first sensor can be operatively connected to feedback signals indicative of current in the first load side connector of the MID to the controller for feedback-based control of the switching device. A second sensor can be operatively connected to feedback signals indicative of current in the second load side connector of the MID to the controller for feedback-based control of the switching device.

At least one communication port can be included, configured for connection to devices outside of the housing. The at least one communication port can be operatively connected to the PCBA for data exchange between the PCBA and an external device.

An electrical panel includes a panel housing defining a back interior surface and having a first line and a second line. A first interior in the panel housing is adjacent the back interior surface. A main breaker is connected mechanically and electrically to the first line and to the second line, and is connected mechanically and electrically to first and second busses of the first interior. A second interior overlies the first interior so the first interior is between the second interior and the back interior surface. A microgrid interconnect device (MID) is included in the panel housing. The MID is connected mechanically and electrically to the main breaker. The MID is connected in electrical series between the main breaker and the second interior.

A plurality of branch circuit breakers can be operatively connected to the second interior to control individual circuits respectively connected to the circuit breakers by respective wires. The MID can include a switching device. A first line side connector can be electrically connected to the switching device and to the first line of the panel housing through the main breaker. A second line side connector can be electrically connected to the switching device and to the second line of the panel housing through the main breaker. A first load side connector can be electrically connected to the switching device and to a first line bus of the second interior. A second load side connector can be electrically connected to the switching device and to a second line bus of the second interior. The switching device can be configured to switch between an MID ON state and an MID OFF state. In the MID ON state, the switching device can electrically connect the first line side connector to the first load side connector and can electrically connect the second line side connector to the second load side connector. In the MID OFF state, the switching device can electrically isolate the first line side connector from the first load side connector and can electrically isolate the second line side connector from the second load side connector.

An MID housing can be included, wherein the switching device is in an interior space of the MID housing. Each of the first load side connector of the MID, the second load side connector of the MID, a first line side connector of the MID, and a second line side connector of the MID can extend from an exterior space, through the housing, and into the interior space of the housing.

A neutral line of the panel housing can connect directly to a neutral bus of the second interior. The second interior can include a back surface at a first elevation in a z-direction defined perpendicular to the back surface. Respective terminals of the first and second line side connectors of the MID can be positioned at a second elevation in the z-direction equal to or offset from the first elevation, configured to be joined by respective posts of a previously-installed interior to load side connectors of a main breaker in an electrical panel. A printed circuit board assembly (PCBA) can be included within the interior space of the MID housing. The PCBA can include a controller configured to control the switching device to switch the switching device between the MID ON state and the MID OFF state. A first sensor can be operatively connected to feedback signals indicative of current in the first load side connector of the MID to the controller for feedback-based control of the switching device. A second sensor can be operatively connected to feedback signals indicative of current in the second load side connector of the MID to the controller for feedback-based control of the switching device. At least one communication port can be included configured for connection to devices outside of the MID housing. The at least one communication port can be operatively connected to the PCBA for data exchange between the PCBA and an external device.

These and other features of the systems and methods of the subject disclosure will become more readily apparent to those skilled in the art from the following detailed description of the disclosed embodiments taken in conjunction with the drawings.

### BRIEF DESCRIPTION OF THE DRAWINGS

So that those skilled in the art to which the subject disclosure appertains will readily understand how to make and use the devices and methods of the subject disclosure without undue experimentation, embodiments thereof will be described in detail herein below with reference to certain figures, wherein:

FIG. 1 is a schematic perspective view of an embodiment of an apparatus constructed in accordance with the present disclosure, showing the microgrid interconnect device (MID) and an interior integrated together for installation in an electrical panel;

FIG. 2 is a schematic perspective view of the apparatus of FIG. 1, showing the sockets in the bottom surface of the interior;

FIG. 3 is a schematic perspective view of the apparatus of FIG. 1, showing the MID housing removed;

FIG. 4 is a schematic perspective view of the apparatus of FIG. 1, showing the line side connectors of the MID;

FIG. 5 is a schematic perspective view of an electrical panel for retrofitting in accordance with methods of the present disclosure, showing the dead panel and circuit breakers;

FIG. 6 is a schematic perspective view of the electrical panel of FIG. 5, showing the dead panel removed and the main breaker switched to the OFF state;

FIG. 7 is a schematic perspective view of the electrical panel of FIG. 5, showing the circuit breakers removed from the interior;

FIG. 8 is a schematic perspective view of a portion of the electrical panel of FIG. 5, showing removal of nuts from the posts of the interior busses and load side connectors of the main breaker;

FIG. 9 is a schematic perspective view of the portion of the electrical panel of FIG. 8, showing the nuts removed;

FIG. 10 is a schematic perspective view of the electrical panel of FIG. 9, showing the apparatus of FIG. 1, including the MID and a new or second interior, being installed into the electrical panel;

FIG. 11 is a schematic perspective view of the electrical panel of FIG. 10, showing the second interior installed on top of the first interior in the electrical panel;

FIG. 12 is a schematic perspective view of a portion of the electrical panel of FIG. 11, showing installation of the nuts back onto the posts of the first interior to mechanically and electrically connect the MID to the load side connectors of the main breaker;

FIG. 13 is a schematic, cross-sectional side elevation view of a portion of the electrical panel of FIG. 12, showing the breaker connectors of the first interior engaged into the sockets of the second interior;

FIG. 14 is a schematic perspective view of the electrical panel of FIG. 12, showing the circuit breakers engaged onto the second interior;

FIG. 15 is a schematic perspective view of the electrical panel of FIG. 14, showing a new dead front mounted to the electrical panel; and

FIG. 16 is a schematic cross-sectional side elevation view of the electrical panel of FIG. 15, showing the layering of the back interior surface of the electrical panel, the first interior, the second interior, the circuit breakers, and the new dead front.

### DETAILED DESCRIPTION

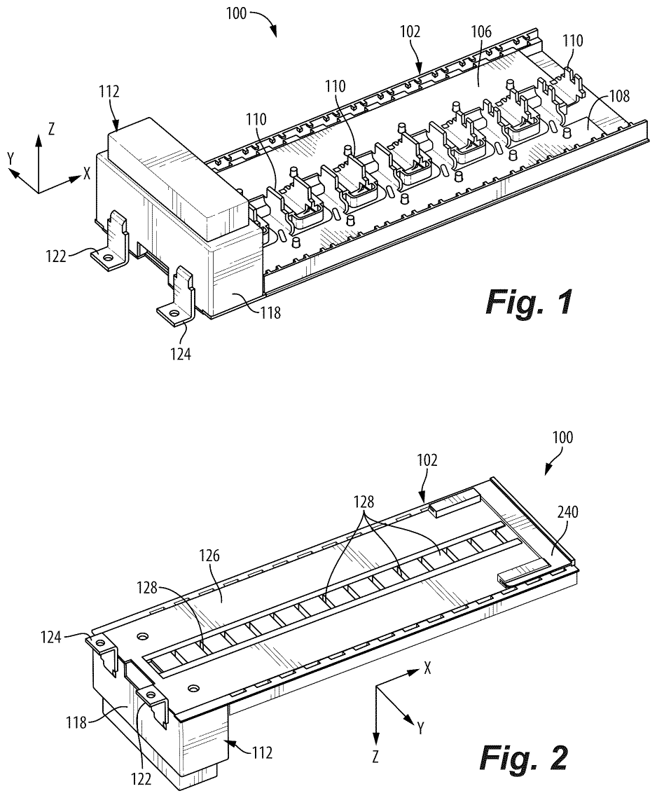

Reference will now be made to the drawings wherein like reference numerals identify similar structural features or aspects of the subject disclosure. For purposes of explanation and illustration, and not limitation, a partial view of an embodiment of an apparatus in accordance with the disclosure is shown in FIG. 1 and is designated generally by reference character 100. Other embodiments of systems in accordance with the disclosure, or aspects thereof, are provided in FIGS. 2-16, as will be described. The systems and methods described herein can be used to retrofit an existing electrical panel to add microgrid interconnect device (MID) functionality to electrical panels, e.g., common service entrance device (CSED) panels, without requiring the utility grid to shut off power to the electrical panels.

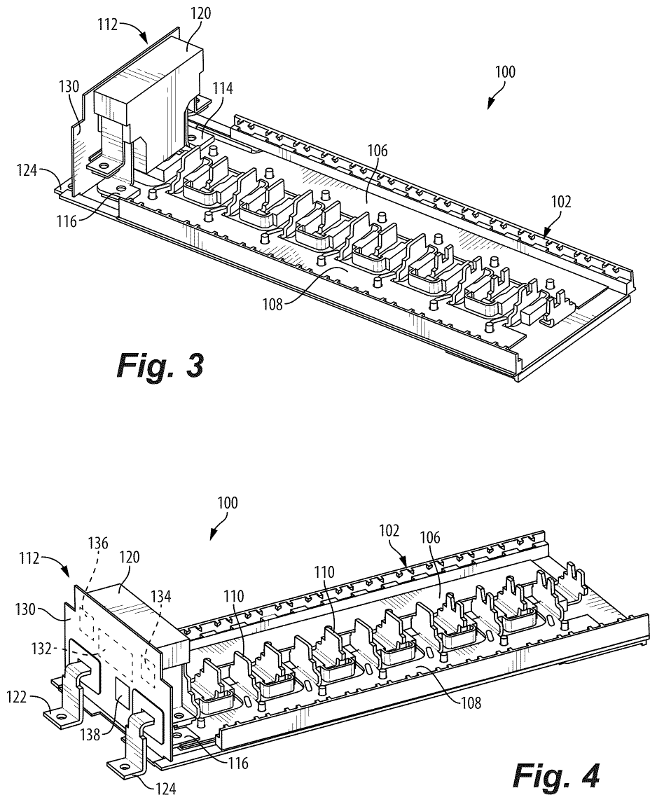

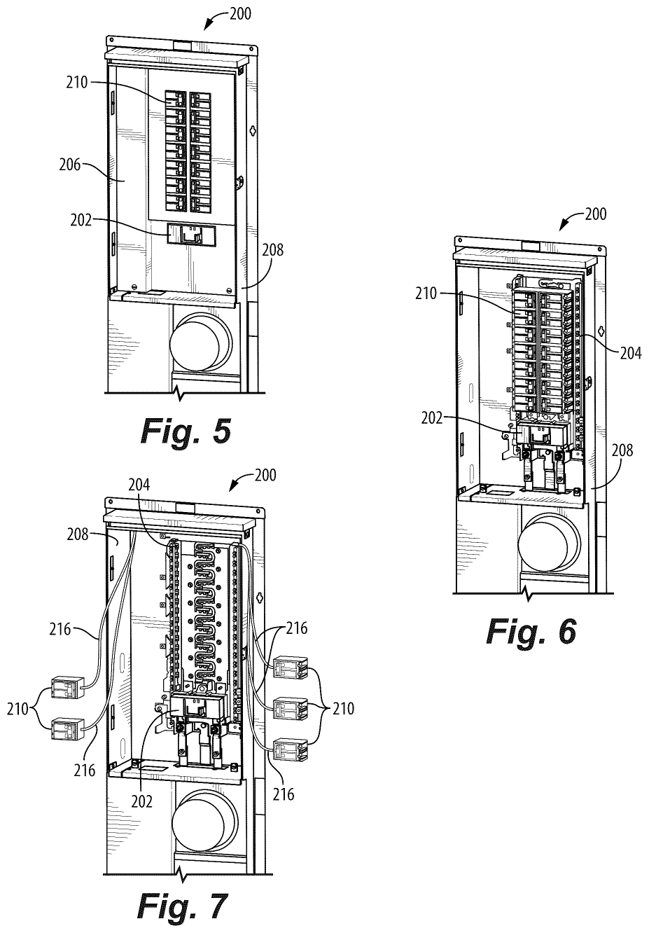

The apparatus 100 includes an interior 102 for an electrical panel 200, shown in FIG. 5. The interior 102 includes a first line bus 106 and a second line bus 108, each with a plurality of breaker connectors 110 extending therefrom, only some of which are labeled in the drawings for sake of clarity. A microgrid interconnect device (MID) 112 is mounted to the interior 102 with a first load side connector 114, labeled in FIG. 3, of the MID 112 connected electrically and mechanically joined, e.g., non-removably, to the first line bus 106. A second load side connector 116 of the MID 112 is connected electrically and mechanically joined to the second line bus 108. The interior 102 and the MID 112 are thus integrated together to be installed as one piece into an electrical panel 200 as described below with reference to FIGS. 5-16.

With reference now to FIG. 3, the MID 112 includes a switching device 120, e.g., a 200 Amp relay. An MID housing 118 is included as shown in FIGS. 1-2 that is shown removed in FIGS. 3-4. The switching device 120 is included in the interior space of the MID housing 118 of FIGS. 1-2. A first line side connector 122 is electrically connected to the switching device 120. A second line side connector 124 is electrically connected to the switching device 120. The first load side connector 114 is electrically connected to the switching device 120. The second load side connector 116 is electrically connected to the switching device 120. Each of the first load side connector 114, the second load side connector 116, the first line side connector 122, and the second line side connector 124 extends from an exterior space, through the MID housing 118, and into the interior space of the MID housing 118, where it connects electrically to the switching device 120.

The switching device 120 is configured to switch between an MID ON state and an MID OFF state. In the MID ON state, the switching device 120 electrically connects the first line side connector 122 to the first load side connector 114, and electrically connects the second line side connector 124 to the second load side connector 116. In the MID OFF state, the switching device 120 electrically isolates the first line side connector 122 from the first load side connector 114, and electrically isolates the second line side connector 124 from the second load side connector 116.

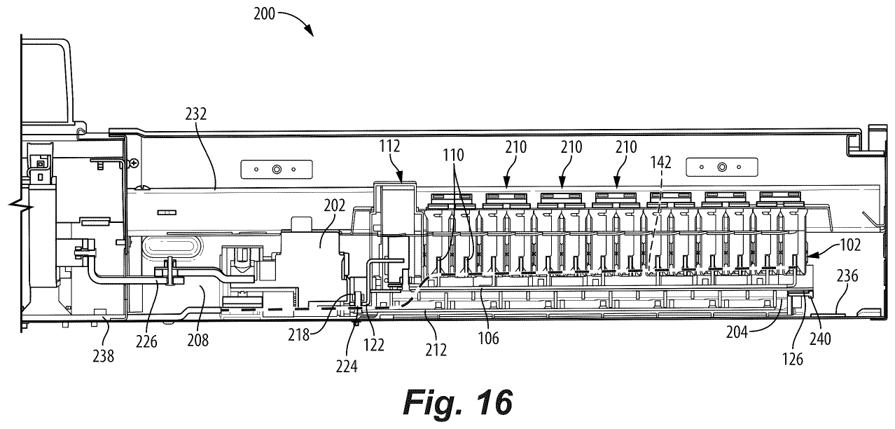

With reference now to FIG. 2, the interior 102 includes a back surface 126 at a first elevation in a z-direction defined perpendicular to the back surface 126, where the z-direction is shown in an x, y, z coordinate system labeled in FIGS. 1-2. Respective terminals of the first and second line side connectors 122, 124 are positioned at a second elevation in the z-direction equal to or offset from the first elevation (e.g., as oriented in FIG. 16, where the connector 122 is offset below the back surface 126 to accommodate installation where the circuit breakers 210 are above the back surface 126). The back surface 126 of the interior 102 includes a plurality of sockets 128, not all of which are labeled in FIG. 2 for sake of clarity.

With reference now to FIGS. 3 and 4, a printed circuit board assembly (PCBA) 130 is included within the interior space of the MID housing 118 shown in FIGS. 1-2. The PCBA 130 includes a controller 132 configured to control the switching device 120 to switch the switching device 120 between the MID ON state and the MID OFF state. A first sensor 134 is operatively connected to feedback signals indicative of current in the first load side connector 114 of the MID 112 to the controller 132 for feedback-based control of the switching device 120, such as for fault protection. A second sensor 136 is operatively connected to feedback signals indicative of current in the second load side connector 116 of the MID 112 to the controller 132 for feedback-based control of the switching device 120, such as for fault protection. At least one communication port 138 is optionally included, configured for connection to devices outside of the housing 118 of FIGS. 1-2, e.g., for monitoring and control of the switching device 120. The at least one communication port 138 is operatively connected to the PCBA 130 for wired or wireless data exchange between the PCBA 130 and an external device.

With reference now to FIG. 5, a method is described of retrofitting an electrical panel 200 to include an apparatus 100 as described above with respect to FIGS. 1-4. The method includes switching the main breaker 202 to an OFF state to disconnect power to a first interior 204, e.g., which can be a traditional interior. The main breaker 202 can be a QOM2 breaker, for example. The method includes removing a dead front 206 from the panel housing 208 to access the first interior 204 as shown in FIG. 6. Then, the plurality of branch circuit breakers 210 can be removed from the first interior 204 as shown in FIG. 7. Prior to removing the circuit breakers 210, the plurality of circuit breakers 210 are installed on the first interior 102, electrically connecting first and second line busses 212, 214 of the first interior 204 to individual branch circuits by load wires 216.

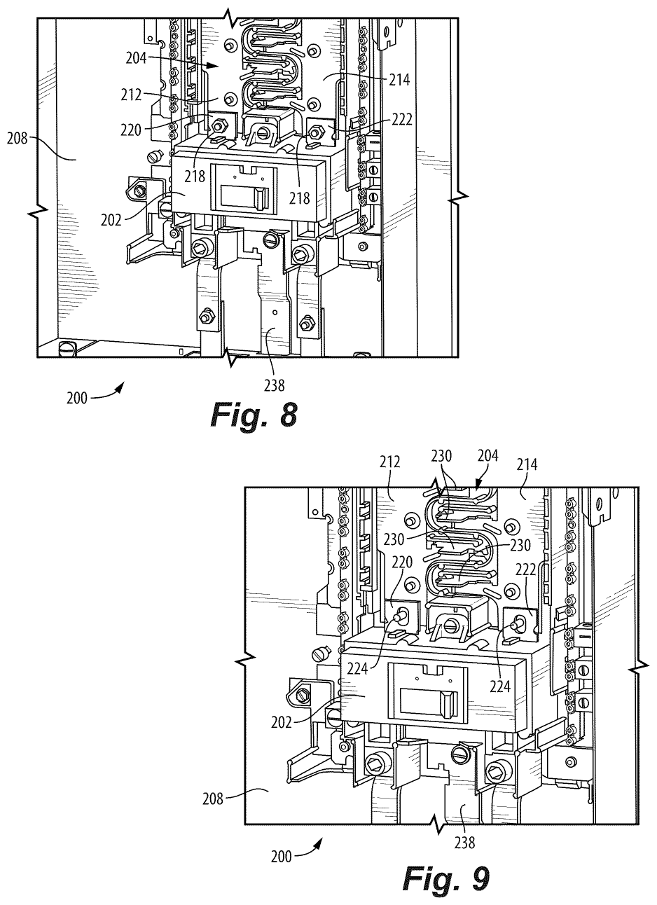

With reference now to FIG. 8, with the circuit breakers 210 removed from the first interior 204 as shown in FIG. 7, the method includes removing one or more nuts 218 mechanically securing one or more corresponding load side electrical connectors 220, 222 of the main breaker 202 to one or more corresponding busses 212, 214 of the first interior 204, leaving the posts 224 of the busses 212, 214 clear as shown in FIG. 9.

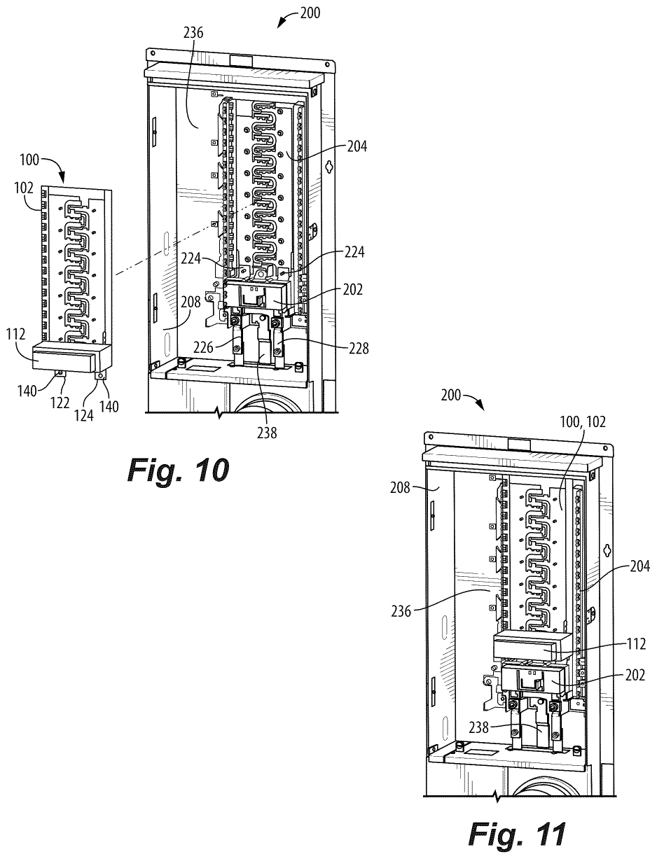

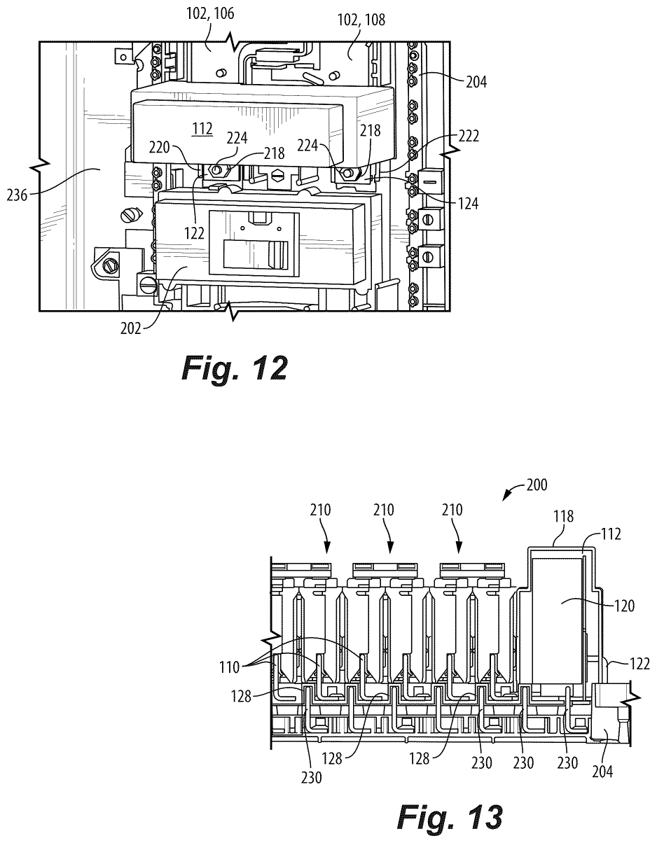

With reference now to FIG. 10, the method includes installing a second interior 102, as described above with reference to FIGS. 1-4, onto the first interior 204, as shown in FIG. 11. As shown in FIG. 12, the method includes connecting the MID 112 in electrical series between the main breaker 202 and the second interior 102, which is performed with the main breaker 202 electrically connected to first and second lines 226, 228 (labeled in FIG. 10) of the panel housing 208, labeled in FIG. 10, but with the main breaker 202 still in the OFF state. A first line side connector 122 is electrically connected to the switching device 120 and is configured to electrically connect to a first load side connector of a main breaker. This connection can be made, as shown in FIG. 12, by securing the line side connectors 122, 124 of the MID 112 to the posts 224 over the load side connectors 220, 222 of the main breaker 202, and then replacing the nuts 218 to the posts 224 over the connectors 122, 124 of the MID 112. Respective holes 140 in the connectors 122, 124, shown in FIG. 10, accommodate the posts 224 passing through the connectors 122, 124.

With reference now to FIG. 13, The first interior 204 includes a plurality of breaker connectors 230 extending from first and second line buses 212, 214 (labeled in FIGS. 7-9). Installing the second interior 102 onto the first interior 204 includes securing the first interior 204 to the second interior 102 by interlocking the plurality of breaker connectors 230 of the first interior 102 into the plurality of sockets 128 of the second interior 102 to hold the first and second interiors 204, 102 together. The busses 106, 108, 212, 214 (labeled in FIGS. 9 and 12) of the first and second interiors 204, 102 are electrically isolated from one another, e.g., by the sockets 128 being of an electrically insulative material.

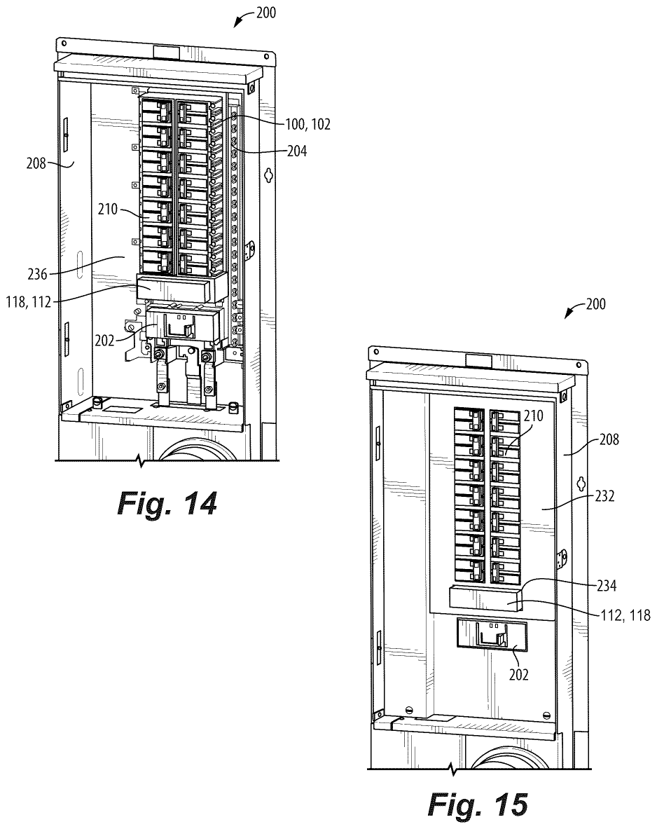

With reference now to FIG. 14, the method further includes mechanically installing the plurality of circuit breakers 210 onto the second interior 102 and electrically connecting first and second line busses 106, 108 (labeled in FIG. 1) of the second interior 102 to each of the circuit breakers 210. The method can include keeping the plurality of circuit breakers 210 electrically connected to the load wires 216 (labeled in FIG. 7) before, during, and after removing the plurality of circuit breakers 210 from the first interior, installing the second interior 102 and the MID 112, and connecting the MID 112 in series between the first and second lines 226, 228 of the electrical panel housing 208 and the main breaker 202, allowing the circuit breakers 210 to hang by load wires 216 as shown in FIG. 7.

Referring now to FIG. 15, after installing the second interior 102 and connecting the MID 112 in electrical series between the main breaker 202 and the second interior 102, the method includes installing a new dead front 232 to the panel housing 208. The new dead front 232 has an additional opening 234 relative to the original dead front 206 of FIG. 5, to allow a portion of the housing 118 of the MID 112 to protrude outward through the dead front 232. At this point, the main breaker 202 can be switched to the ON state. With the main breaker 202 in the ON state, the main breaker 202 electrically connects a first line 226 (labeled in FIG. 10) of the electrical panel housing 208 in series with the first line side connector 122 (labeled in FIG. 10) of the MID 112 and electrically connects a second line 228 (labeled in FIG. 10) of the electrical panel 200 in series with the second line side connector 124 (labeled in FIG. 10) of the MID 112, and with the main breaker in an OFF state, these electrical connections are disconnected. With the MID 112 in an ON state, the MID 112 connects the first line side connector 122 (labeled in FIG. 10) of the MID 112 to the first line bus 106 (labeled in FIG. 10) of the second interior 102 and connects the second line side connector 124 (labeled in FIG. 10) of the MID 112 to a second line bus 108 (labeled in FIG. 10) of the second interior 102, whereas in an the OFF state of the MID, these electrical connections are disconnected. When both the MID 112 and the main breaker 202 are in their ON states, power from a utility grid can be supplied to the loads connected to the circuit breakers 210. If either or both of the MID 112 and the main breaker 202 are in their OFF state, no power from the utility will reach the loads connected to the circuit breakers 210. With the main breaker 202 in its ON state, the MID 112 can switch from its ON state supplying power to the loads from the utility grid, to its OFF state islanding the loads from the utility grid. One or more of the circuit breakers 210 can be used to connect one or more sources of power to the interior 102 to power the loads in this islanded or microgrid state.

With reference now to FIG. 16, after the retrofit method, the electrical panel 200 includes a panel housing 208 defining a back interior surface 236. The first interior 204 in the panel housing 208 is adjacent the back interior surface 236. The second interior 102 overlies the first interior 204 so the first interior 204 is between the second interior 102 and the back interior surface 236. The plurality of circuit breakers 210 is operatively connected to the second interior 102 to control individual circuits respectively connected to the circuit breakers 210 by respective wires 216, labeled in FIG. 7. Optionally, a neutral line 238 of the panel housing 208 can electrically connect directly to a neutral bus 142 of the second interior 102, as indicated by the broken lines in FIG. 16. The end of the second interior 102 opposite the MID 112 includes a bracket 240 that can clip to the first interior 204 to help secure the new interior 102 to the previously-installed interior 204.

Systems and methods as disclosed herein provide various potential benefits including but not limited to the following. A traditional electrical panel can be retrofitted to include an MID for microgrid functionality without requiring a power shut off by the utility grid. The thinner the MID is in the horizontal direction as oriented in FIG. 16, the greater the number of individual circuit breakers can be accommodated. The MID can be designed to provide horizontal clearance (as oriented in FIG. 16) for access to the nuts 218 labeled in FIG. 12 for installation and removal of the MID and new interior.

The methods and systems of the present disclosure, as described above and shown in the drawings, provide for retrofitting existing electrical panels to add MID functionality without requiring the utility grid to shut off power to the electrical panels. While the apparatus and methods of the subject disclosure have been shown and described with reference to certain embodiments, those skilled in the art will readily appreciate that changes and/or modifications may be made thereto without departing from the scope of the subject disclosure.

What is claimed is:

1. A method of retrofitting an electrical panel comprising:
removing a plurality of branch circuit breakers from a first interior in a panel housing;
installing a second interior onto the first interior; and
connecting a microgrid interconnect device (MID) in electrical series between a main breaker and the second interior.

2. The method as recited in claim 1, wherein connecting the MID includes:
electrically connecting a first line side connector of the MID to a first load side connector of the main breaker;
electrically connecting a second line side connector of the MID to a second load side connector of the main breaker;
wherein with the main breaker in an ON state, the main breaker electrically connects a first line of the electrical panel housing in series with the first line side connector of the MID and electrically connects a second line of the electrical panel housing in series with the second line side connector of the MID, and
wherein with the MID in an ON state, the MID electrically connects the first line side connector of the MID to a first line bus of the second interior and electrically connects the second line side connector of the MID to a second line bus of the second interior.

3. The method as recited in claim 1, wherein prior to removing the circuit breakers, the plurality of circuit breakers are installed on the first interior, electrically connecting first and second line busses of the first interior to individual branch circuits by load wires, and further comprising:
mechanically installing the plurality of circuit breakers onto the second interior, electrically connecting first and second line busses of the second interior to each of the circuit breakers of the plurality of circuit breakers; and
keeping the plurality of circuit breakers electrically connected to the load wires before, during, and after removing the plurality of circuit breakers from the first interior, installing the second interior and the MID, and connecting the MID in electrical series between the first and second lines of the electrical panel housing and the main breaker.

4. The method as recited in claim 1, further comprising:
switching the main breaker to an OFF state to disconnect power to the first interior and removing a dead front from the panel housing to access the first interior before removing the plurality of circuit breakers from the first interior, wherein connecting the MID in electrical series between the main breaker and the second interior is performed with the main breaker electrically connected to first and second lines of the panel housing.

5. The method as recited in claim 1, wherein the first interior includes a plurality of breaker connectors extending from a first line bus and form a second line bus, wherein the second interior includes a plurality of sockets, and wherein installing the second interior onto the first interior includes securing the first interior to the second interior by interlocking the plurality of breaker connectors of the first interior into the plurality of sockets of the second interior to hold the first and second interiors together.

6. The method as recited in claim 1, further comprising:
prior to removing the plurality of breakers from the first interior, removing a dead front from the panel housing to provide access to the first interior; and
after installing the second interior and connecting the MID in electrical series between the main breaker and the second interior, installing a new dead front to the panel housing.

7. An apparatus comprising:
an interior for an electrical panel, wherein the interior includes a first line bus and a second line bus, each with a plurality of breaker connectors extending therefrom; and
a microgrid interconnect device (MID) mounted to the interior with a first load side connector of the MID connected electrically and mechanically joined to the first line bus, and with a second load side connector of the MID connected electrically and mechanically joined to the second line bus.

8. The apparatus as recited in claim 7, further comprising an MID housing, wherein a switching device is in an interior space of the MID housing, wherein each of the first load side connector of the MID, the second load side connector of the MID, a first line side connector of the MID, and a second line side connector of the MID extends from an exterior space, through the MID housing, and into the interior space of the MID housing to electrically connect to the switching device.

9. The apparatus as recited in claim 8, wherein the interior includes a back surface at a first elevation in a z-direction defined perpendicular to the back surface, wherein respective terminals of the first and second line side connectors of the MID are positioned at a second elevation in the z-direction offset from the first elevation, configured to be joined by respective posts of a previously-installed interior to load side connectors of a main breaker in an electrical panel.

10. The apparatus as recited in claim 9, wherein the back surface of the interior includes a plurality of sockets configured to receive a plurality of breaker connectors extending from line busses of the previously-installed interior for securing the interior to the previously-installed interior by interlocking the plurality of breaker connectors of the previously-installed interior into the plurality of sockets.

11. The apparatus as recited in claim 8, further comprising:
a printed circuit board assembly (PCBA) within the interior space of the MID housing, wherein the PCBA includes a controller configured to control the switching device to switch the switching device between the MID ON state and the MID OFF state;
a first sensor operatively connected to feedback signals indicative of current in the first load side connector of the MID to the controller for feedback-based control of the switching device; and
a second sensor operatively connected to feedback signals indicative of current in the second load side connector of the MID to the controller for feedback-based control of the switching device.

12. The apparatus as recited in claim 11, further comprising at least one communication port configured for connection to devices outside of the housing, wherein the at least one communication port is operatively connected to the PCBA for data exchange between the PCBA and an external device.

13. An electrical panel comprising:
a panel housing defining a back interior surface and including a first line and a second line;
a first interior in the panel housing adjacent the back interior surface;
a main breaker connected mechanically and electrically to the first line and to the second line, and connected mechanically and electrically to first and second busses of the first interior;
a second interior overlying the first interior so the first interior is between the second interior and the back interior surface; and
a microgrid interconnect device (MID) in the panel housing, wherein the MID is connected mechanically and electrically to the main breaker, wherein the MID is connected in electrical series between the main breaker and the second interior.

14. The electrical panel as recited in claim 13, further comprising a plurality of circuit breakers operatively connected to the second interior to control individual circuits respectively connected to the circuit breakers by respective wires.

15. The electrical panel as recited in claim 13, wherein the MID includes:
a switching device;
a first line side connector electrically connected to the switching device and to the first line of the panel housing through the main breaker;
a second line side connector electrically connected to the switching device and to the second line of the panel housing through the main breaker;
a first load side connector electrically connected to the switching device and to a first line bus of the second interior; and
a second load side connector electrically connected to the switching device and to a second line bus of the second interior;
wherein the switching device is configured to switch between an MID ON state and an MID OFF state,
wherein in the MID ON state, the switching device electrically connects the first line side connector to the first load side connector and electrically connects the second line side connector to the second load side connector, and
wherein in the MID OFF state, the switching device electrically isolates the first line side connector from the first load side connector and electrically isolates the second line side connector from the second load side connector.

16. The electrical panel as recited in claim 15, further comprising an MID housing, wherein the switching device is in an interior space of the MID housing, wherein each of the first load side connector of the MID, the second load side connector of the MID, the first line side connector of the MID, and the second line side connector of the MID extends from an exterior space, through the housing, and into the interior space of the housing.

17. The electrical panel as recited in claim 16, wherein a neutral line of the panel housing connects directly to a neutral bus of the second interior.

18. The electrical panel as recited in claim 16, wherein the second interior includes a back surface at a first elevation in a z-direction defined perpendicular to the back surface, wherein respective terminals of the first and second line side connectors of the MID are positioned at a second elevation in the z-direction offset from the first elevation, configured to be joined by respective posts of a previously-installed interior to load side connectors of a main breaker in an electrical panel.

19. The electrical panel as recited in claim 16, further comprising:
a printed circuit board assembly (PCBA) within the interior space of the MID housing, wherein the PCBA includes a controller configured to control the switching device to switch the switching device between the MID ON state and the MID OFF state;
a first sensor operatively connected to feedback signals indicative of current in the first load side connector of the MID to the controller for feedback-based control of the switching device; and
a second sensor operatively connected to feedback signals indicative of current in the second load side connector of the MID to the controller for feedback-based control of the switching device.

20. The electrical panel as recited in claim 19, further comprising at least one communication port configured for connection to devices outside of the MID housing, wherein the at least one communication port is operatively connected to the PCBA for data exchange between the PCBA and an external device.
